(19) United States
(12) Patent Application Publication
(10) Pub. No.: US 2024/0065071 A1
(43) Pub. Date: Feb. 22, 2024

(54) ORGANIC LIGHT EMITTING DEVICE AND MANUFACTURING METHOD THEREOF, AND DISPLAY DEVICE

(71) Applicant: Shenzhen China Star Optoelectronics Semiconductor Display Technology Co., Ltd., Shenzhen (CN)

(72) Inventors: Guangda LI, Shenzhen (CN); Ming LIU, Shenzhen (CN); Ting SHI, Shenzhen (CN)

(21) Appl. No.: 17/618,556

(22) PCT Filed: Nov. 18, 2021
(86) PCT No.: PCT/CN2021/131475

§ 371 Date: May 4, 2023

(30) Foreign Application Priority Data
Oct. 27, 2021 (CN) 202111256184.4

(51) Int. Cl. H10K 59/60; H10K 50/15; H10K 50/16; H10K 50/17; H10K 59/80; H10K 71/60

(52) U.S. Cl. CPC H10K 59/60; H10K 50/15; H10K 50/16; H10K 50/171; H10K 59/8792; H10K 59/805; H10K 71/60; H10K 2102/351

(57) ABSTRACT

An organic light emitting device and a manufacturing method thereof, and a display device are provided. The organic light emitting device includes a first electrode disposed on an array substrate, a light emitting module disposed on the first electrode, a second electrode disposed on the light emitting module, a photovoltaic module disposed on the second electrode, and a third electrode disposed on the photovoltaic module.

### FIELD OF INVENTION

The present invention relates to the field of display apparatuses, and in particular, to an organic light emitting device and a manufacturing method thereof, and a display device.

### BACKGROUND OF INVENTION

As a new display technology, the ink-jet printing organic light emitting diode (IJP OLED) has characteristics, such as active light emission, low energy consumption, a high color gamut, a high contrast, zero delay, transparent display, flexible display, and free display forms, which has incomparable advantages than the thin film transistor liquid crystal display (TFT-LCD) technology. Since the IJP OLED does not require a backlight source, the structure is simpler than that of the TFT-LCD, and display products can be thinner and lighter. In addition, the IJP OLED requires a lower driving voltage and lower energy consumption for operation.

As another branch in the field of organic optoelectronics, organic solar cells have advantages, such as low costs, light weights, processibility using solutions, flexibility, foldability, and productibility by roll-to-roll printing. More importantly, the organic solar cells may be processed using a solution method, such as a knife coating method, a slit coating method, a silk-screen printing method, or an ink-jet printing method. By manufacturing the IJP OLED and the organic solar cells using the ink-jet printing method photovoltaic power generation of the organic solar cells and electroluminescence of the IJP OLED are integrated together, which is of significance to broadening the application scope of the optoelectronic technology.

### SUMMARY OF INVENTION

The present invention is intended to provide an organic light emitting device and a manufacturing method thereof, and a display device, to resolve the technical problem that an organic light emitting device in the prior art has merely a single function.

In order to realize the above objects, the present invention provides an organic light emitting device. The organic light emitting device includes an array substrate, a light emitting module, a photovoltaic module, a first electrode, a second electrode, and a third electrode. The first electrode is disposed on the array substrate. The light emitting module is disposed on the first electrode. The second electrode is disposed on a surface of the light emitting module away from the first electrode. The photovoltaic module is disposed on a surface of the second electrode away from the light emitting module. The third electrode is disposed on a surface of the photovoltaic module away from the second electrode.

Further, the light emitting module includes a light emitting layer, a first hole function layer, and a first electron function layer. The light emitting layer is disposed between the first electrode and the second electrode. The first hole function layer is disposed between the light emitting layer and the first electrode. The first electron function layer is disposed between the light emitting layer and the second electrode.

Further, the first hole function layer includes a first hole transport layer and a first hole injection layer. The first electron function layer includes a first electron transport layer and a first electron injection layer.

The first hole transport layer is disposed on a surface of the light emitting layer away from the first electron function layer. The first hole injection layer is disposed on a surface of the first hole transport layer away from the light emitting layer. The first electron transport layer is disposed on a surface of the light emitting layer away from the first hole function layer. The first electron injection layer is disposed on a surface of the first electron transport layer away from the light emitting layer.

Further, the photovoltaic module includes a light absorption layer, a second electron function layer, and a second hole function layer. The light absorption layer is disposed between the second electrode and the third electrode. The second electron function layer is disposed between the light absorption layer and the second electrode. The second hole function layer is disposed between the light absorption layer and the third electrode.

Further, materials of the first electrode and the third electrode include transparent conductive oxide, and a material of the second electrode includes metal.

Further, a thickness of the first electrode ranges from 10 to 50 nanometers. A thickness of the second electrode ranges from 100 to 200 nanometers. a thickness of the third electrode ranges from 50 to 80 nanometers;

The present invention further provides a method for manufacturing an organic light emitting device. The manufacturing method includes steps of: manufacturing a first electrode on an array substrate; manufacturing a light emitting module on the first electrode; manufacturing a second electrode on the light emitting module; manufacturing a photovoltaic module on the second electrode; and manufacturing a third electrode on the photovoltaic module.

Further, the step of manufacturing the light emitting module on the first electrode includes manufacturing a first hole function layer on the first electrode; manufacturing a light emitting on the first hole function layer; and manufacturing a first electron function layer on the light emitting layer.

Further, the step of manufacturing the photovoltaic module on the second electrode includes: manufacturing a second electron function layer on the second electrode; manufacturing a light absorption layer on the second electron function layer; and manufacturing a second hole function layer on the light absorption layer.

The present invention further provides a display device. The display device includes the above organic light emitting device.

Beneficial Effects: The present invention has the following advantages. In the organic light emitting device provided in the present invention, the light emitting module using an organic light emitting diode (OLED) technology is combined with the photovoltaic module using an organic solar photovoltaic cell technology, so that the organic light emitting device can achieve self-powering and self-illumination without an external power supply. Therefore, consumption of electric energy is reduced, and the working time of the display device is prolonged. In addition, the method for manufacturing an organic light emitting device provided in the present invention has a simple process and requires no additional production apparatus. Therefore, the production costs are reduced.

### BRIEF DESCRIPTION OF DRAWINGS

To describe the technical solutions in the embodiments of the present invention more clearly, the following briefly describes the accompanying drawings required for describing the embodiments. Apparently, the accompanying drawings in the following description show merely some embodiments of the present invention, and a person skilled in the art may still derive other drawings from these accompanying drawings without creative efforts.

FIG. 1 is a schematic diagram of a layered structure of an organic light emitting device according to an embodiment of the present invention.

FIG. 2 is a schematic flowchart of a method for manufacturing an organic light emitting device according to an embodiment of the present invention.

### REFERENCE NUMERALS

Organic light emitting device 1; Array substrate 10;
First electrode 20; Light emitting module 30;
First hole function layer 31; First hole injection layer 311;
First hole transport layer 312; Emission layer 32;
First electron function layer 33; First electron transport layer 331;
First electron injection layer 332; Second electrode 40;
Photovoltaic module 50; Second electron function layer 51;
Light absorption layer 52; Second hole function layer 53;
Third electrode 60.

### DETAILED DESCRIPTION OF PREFERRED EMBODIMENTS

The following describes the exemplary embodiments of the present invention with reference to accompanying drawings of the specification to prove that the present invention can be implemented. The embodiments can describe the present invention completely to a person skilled in the art, to make the technical content clearer and easier to understand. The present invention can be represented through various embodiments in different forms, and the protection scope of the present invention is not limited to the embodiments mentioned in the specification.

In the accompanying drawings, components with the same structures are denoted by the same numerals, and components with similar structures or functions are denoted by similar numerals. The size and thickness of each component shown in the accompanying drawings are shown arbitrarily, and the size and thickness of each component are not limited in the present invention. To make the accompanying drawings clearer, a certain part of the accompanying drawings exaggerates the thickness of components appropriately.

In addition, the following description of various embodiments is provided to exemplify specific embodiments of the present invention for implementation with reference to the accompanying drawings. The directional terms mentioned in the present invention, such as “above”, “below”, “front”, “back”, “left”, “right”, “inside”, “outside”, or “side” merely refer to the directions in the accompanying drawings. Therefore, the used directional terms are merely used for describing and understanding the present invention better and more clearly, rather than indicating or implying that the mentioned apparatus or element needs to have a particular direction, or be constructed and operated in a particular direction, and therefore cannot be understood as a limitation to the present invention. In addition, terms “first”, “second”, and “third” are used merely for descriptive purposes and are not to be construed as indicating or implying relative importance.

When a component is described as “on” another component, the component may be directly disposed on the another component; or an intermediate component may exist, the component is disposed on the intermediate component, and the intermediate component is disposed on another component. When a component is described as “be mounted to” or “be connected to” another component, the “be mounted to” or “be connected to” can be understood as directly “mount” or “connect”, or a component “is mounted to” or “is connected to” another component through an intermediate component.

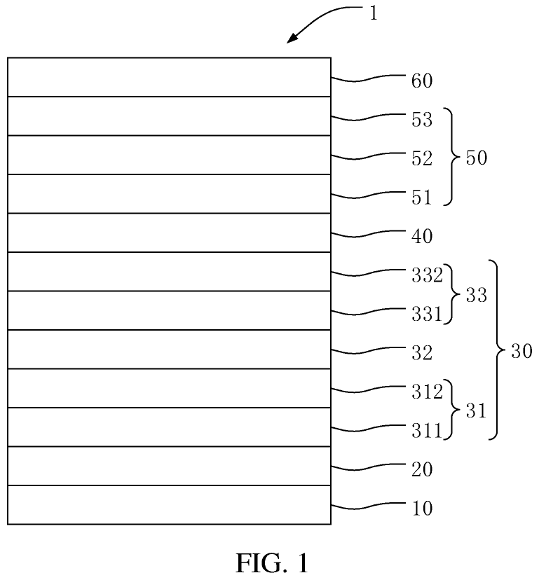

An embodiment of the present invention provides a display device. A plurality of organic light emitting devices 1 are disposed in the display device. The organic light emitting devices 1 can convert solar energy to electric energy, and then convert the electric energy to light energy, so as to realize self-powering and self-illumination. As shown in FIG. 1, each of the organic light emitting devices 1 includes an array substrate 10, a light emitting module 30, a photovoltaic module 50, and a first electrode 20, a second electrode 40, and a third electrode 60 that electrically connect the modules.

A plurality of thin film transistors are disposed in the array substrate 10, and are configured to control a pixel circuit to be turned on or off. A base of the array substrate 10 may be a rigid base or a flexible base. The rigid base includes glass, quartz, and the like. The flexible base may be polyimide (PI), polyethylene terephthalate (PET), polyethylene naphthalate (PEN), or the like. A type of the thin film transistors may be one or more of a metal oxide (indium gallium zinc oxide (IGZO)) type, a low temperature polycrystalline oxide (LTPO) type, a low temperature polysilicon (LTPS) type, or an amorphous silicon (a-Si) type.

The first electrode 20 is disposed on the array substrate 10, and is electrically connected to the thin film transistors in the array substrate 10. The second electrode 40 is disposed on a side of the first electrode 20 away from the array substrate 10. The light emitting module 30 is disposed between the first electrode 20 and the second electrode 40. The third electrode 60 is disposed on a side of the second electrode 40 away from the light emitting module 30. The photovoltaic module 50 is disposed between the second electrode 40 and the third electrode 60.

In an embodiment of the present invention, the first electrode 20 is used as a positive electrode of the light emitting module 30 to provide holes for the light emitting module 30. The second electrode 40 is used as a negative electrode of the light emitting module 30 to provide electrons for the light emitting module 30. The second electrode 40 is a common electrode, and is also a negative electrode of the photovoltaic module 50 to transport electrons for the photovoltaic module 50. The third electrode 60 is used as a positive electrode of the photovoltaic module 50 to transport holes for the photovoltaic module 50.

In an embodiment of the present invention, the organic light emitting device 1 is a bottom-emitting OLED device. Light emitted by the light emitting module 30 exits from a surface of the array substrate 10 away from the first electrode 20, that is, exits from a bottom surface of the organic light emitting device 1. In order to guarantee the light emitting rate of the light emitting module 30, the first electrode 20 is configured as a transparent electrode. A material of the first electrode 20 includes transparent conductive oxide, such as indium tin oxide (ITO) and indium zinc oxide (IZO). A film thickness of the first electrode 20 ranges from 10 to 50 nanometers.

Since the display light exits from the bottom surface of the organic light emitting device 1, a light entry surface of the photovoltaic module 50 is a top surface of the organic light emitting device 1, namely, a surface of the third electrode 60 away from the photovoltaic module 50. In order to guarantee an incident light amount of the photovoltaic module 50, the third electrode 60 is also configured as a transparent electrode. The third electrode 60 is also made of the transparent conductive oxide. A film thickness of the third electrode 60 ranges from 50 to 80 nanometers.

In order to prevent the light emitted by the light emitting module 30 from affecting the operation of the photovoltaic module 50, and to prevent sunlight of the photovoltaic module 50 from affecting the operation of the light emitting module 30, the second electrode 40 is a total reflection electrode. In this way, not only can the light emitting module 30 and the photovoltaic module 50 be prevented from affecting each other, but also the utilization of the light in the light emitting module 30 and the photovoltaic module 50 can be increased, thereby improving the brightness of the organic light emitting device 1. In detail, a material of the second electrode 40 includes reflective metal having excellent conductivity, such as silver, aluminum, gold, copper, molybdenum, or titanium. A film thickness of the second electrode 40 ranges from 100 to 200 nanometers.

The sunlight is incident on a light entry surface of the organic light emitting device 1, and then passes through the photovoltaic module 50 to convert light energy to electric energy. The generated electric energy can be directly supplied to the light emitting module 30 under the photovoltaic module 50. The light emitting module 30 converts the electric energy to the light energy to realize solar light emission. The light energy generated by the photovoltaic module 50 may also be temporarily stored in a storage battery. When no external power supply is available, the light emitting module 30 may be powered by the electric energy stored in the storage battery.

The light emitting module 30 is disposed on a surface of the first electrode 20 away from the array substrate 10, and is electrically connected to the array substrate 10 using the first electrode 20. The light emitting module 30 includes a first hole function layer 31, a light emitting layer 32, and a first electron function layer 33. The light emitting layer 32 is located between the first hole function layer 31 and the first electron function layer 33. A material of the light emitting layer includes a fluorescent material. The first hole function layer 31 and the first electron function layer 33 converge holes in the first electrode 20 and electrons in the second electrode 40 into the light emitting layer 32 and combine the holes and the electrons. The fluorescent material in the light emitting layer 32 is excited to emit light, so as to provide a display light source for the display device.

The first hole function layer 31 includes a first hole injection layer 311 and a first hole transport layer 312. The first electron function layer 33 includes a first electron transport layer 331 and a first electron injection layer 332.

The first hole injection layer 311 is disposed on a surface of the first electrode 20 away from the array substrate 10, and is made of an organic hole injection material. The organic hole injection material includes tetrafluorotetracyanoquinodimethane, 7,7,8,8-tetracyanoquinodimethane, HATCN, and the like. The hole injection layer is configured to acquire the holes in the first electrode 20, and inject the holes into the first hole transport layer 312.

The first hole transport layer 312 is disposed on a surface of the first hole injection layer 311 away from the first electrode 20, and is made of an organic hole transport material. The organic hole transport material includes N,N′-diphenyl-N,N′-(1-naphthalenyl)-1,1′-biphenyl-4,4′-diamine, N,N′-diphenyl-N,N′-bis (3-methylphenyl)-1,1′-biphenyl-4,4′-diamine, TFB, and the like. The hole transport layer has a hole carrier transport function, and is configured to transport holes in the hole injection layer into the light emitting layer 32.

The first electron transport layer 331 is disposed on a surface of the light emitting layer 32 away from the first hole transport layer 312, and has an electron carrier transport function. The first electron transport layer 331 is configured to transport electrons in the electron injection layer into the light emitting layer 32.

The first electron injection layer 332 is disposed on a surface of the first electron transport layer 331 away from the light emitting layer 32. The first electron injection layer is configured to acquire electrons in the second electrode 40, and inject the electrons into the first electron transport layer 331.

The first electron transport layer 331 and the first electron injection layer 332 are made of a same organic electronic material or different organic electronic materials. The organic electronic material is one or more of an inorganic material having a relatively low vacuum level, an organic material having a relatively low lowest unoccupied molecular orbital (LUMO), or an organic doped material. The organic electron injection material includes alkali metal oxide, alkaline earth metal oxide, an alkali metal carbonate compound, an alkaline earth metal carbonate compound, alkali metal fluoride, alkaline earth metal fluoride, alkaline earth metal hydroxide, alkali metal hydroxide, and the like, for example, zinc oxide, lithium fluoride, 8-hydroxyquinoline-lithium, calcium fluoride, magnesium fluoride, sodium fluoride, potassium fluoride, barium fluoride, cesium fluoride, cesium hydroxide, cesium carbonate, and zinc magnesium oxide.

The photovoltaic module 50 is disposed on a surface of the second electrode 40 away from the light emitting module 30, and includes a second electron function layer 51, a light absorption layer 52, and a second hole function layer 53. The light absorption layer 52 is located between the second electron function layer 51 and the second hole function layer 53. The light absorption layer 52 is a blend of a p-type organic semiconductor and an n-type organic semiconductor, and may be but is not limited to one or more of PTB7-TH, PM6, Y6, or poly(2,7-bis(2-octyldodecyl)benzo[LMN] [3,8]phenanthroline-1,3,6,8 (2H,7H)-tetraketone-4,9-diyl)([2,2]dithienyl-5,5′-diyl). The light causes a semiconductor p-n junction in the light absorption layer 52 to generate a new electron-hole pair, and an electric field of the p-n junction causes electrons and holes to move to two sides of the junction, forming an additional potential difference, thereby generating electric energy by means of a photovoltaic effect.

The second electron function layer 51 includes a second electron transport layer, and is disposed between the second electrode 40 and the light absorption layer 52. The second electron function layer 51 is also made of the organic electronic material. Organic electronic materials used in the second electron function layer include alkali metal oxide, alkaline earth metal oxide, an alkaline metal carbonate compound, an alkaline earth metal carbonate compound, alkali metal fluoride, and the like, for example, zinc oxide, lithium fluoride, PFN, calcium fluoride, and cesium carbonate. The second hole function layer 53 includes a second hole transport layer, and is disposed between the light absorption layer 52 and the third electrode 60. The second hole function layer 53 is made of the organic hole transport material.

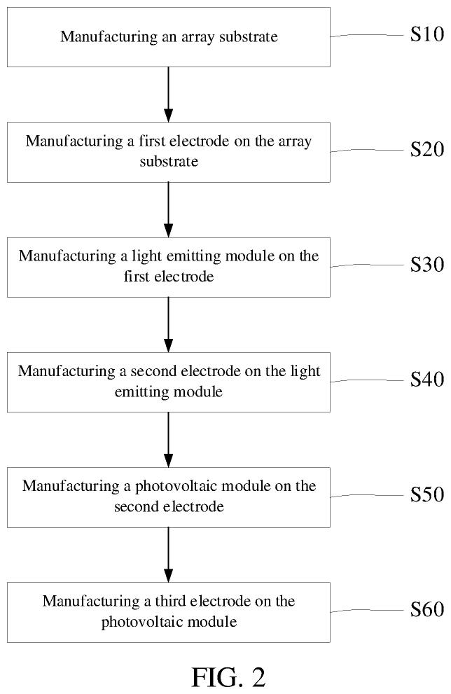

An embodiment of the present invention further provides a method for manufacturing an organic light emitting device 1, to manufacture the above organic light emitting device 1. A process of the method for manufacturing an organic light emitting device 1 is shown in FIG. 2, and includes the steps as follows.
Step S10): Manufacturing of an array substrate 10, including manufacturing a thin film transistor on a base using a thin film transistor process to form the array substrate 10.
Step S20): Manufacturing of a first electrode 20 on the array substrate 10, including: sputtering a layer of ITO having a thickness of 15 nanometers on the array substrate 10, and patterning the ITO using a lithography technology, so as to form the first electrode 20.
Step S30): Manufacturing of a light emitting module 30 on the first electrode 20, including: successively manufacturing a first hole function layer 31, a light emitting layer 32, and a first electron function layer 33 on a surface of the first electrode 20 away from the array substrate 10 using an inkjet printing process, and combining the first hole function layer 31, the light emitting layer 32, and the first electron function layer 33 to form the light emitting module 30. The light emitting layer 32 is made of 3,6bis(tert-butyl)carbazole doped with platinum octaethylporphyrin (PtOEP, with a mass ratio of 20%), and has a thickness of 40 nanometers.

In detail, the step of manufacturing the first hole function layer 31 includes: successively forming a first hole injection layer 311 having a thickness of 15 nanometers and a first hole transport layer 312 having a thickness of 20 nanometers on the surface of the first electrode 20 away from the array substrate 10 using the inkjet printing process. The first hole injection layer 311 is made of HATCN. The first hole transport layer 312 is made of TFB.

The step of manufacturing the first electron function layer 33 includes: successively forming a first electron transport layer 331 having a thickness of 20 nanometers and a first electron injection layer 332 having a thickness of 10 nanometers on a surface of the light emitting layer 32 away from the first hole function layer 31 using the inkjet printing process. The first electron transport layer 331 is made of TAZ. The first electron injection layer 332 is made of zinc oxide.

Step S40): Manufacturing of a second electrode 40 on the light emitting module 30, including manufacturing a layer of metallic silver having a thickness of 150 nanometers on a surface of the first electron function layer 33 away from the light emitting layer 32 using a sputtering process or an evaporation process to form the second electrode 40.

Step S50): Manufacturing of a photovoltaic module 50 on the second electrode 40, including: successively manufacturing a second electron function layer 51, a light absorption layer 52, and a second hole function layer 53 on a surface of the second electrode 40 away from the light emitting module 30 using the inkjet printing process. The light absorption layer 52 is a PM6:Y6 blending film, and has a thickness of 100 nanometers.

In detail, the step of manufacturing the second electron function layer 51 includes: forming a second electron transport layer having a thickness of 20 nanometers on a surface of the second electrode 40 away from the first electron function layer 33 using the inkjet printing process, wherein the second electron transport layer is made of the zinc oxide.

The step of manufacturing the second hole function layer 53 includes: forming a second hole transport layer having a thickness of 40 nanometers on a surface of the light absorption layer 52 away from the second electron function layer 51 using the inkjet printing process, wherein the second hole transport layer is made of PEDOT:PSS.

Step S60): Manufacturing of a third electrode 60 on the photovoltaic module 50, including manufacturing a layer of ITO having a thickness of 100 nanometers on a surface of the photovoltaic module 50 away from the second electrode 40 using the sputtering process to form the third electrode 60.

According to the organic light emitting device provided in the embodiments of the present invention, the OLED technology is combined with the organic solar photovoltaic cell technology, the photovoltaic module using the organic solar photovoltaic cell technology is configured to convert the light energy to the electric energy, and provide the converted electric energy to the light emitting module, and the light emitting module using the OLED technology converts the electric energy to the light energy to provide a light source for display, thereby achieving solar light emission. In this way, the organic light emitting device can achieve self-powering and self-illumination without an external power supply. Therefore, consumption of electric energy is reduced, and the working time of the display device is prolonged.

In addition, according to the organic light emitting device, the second electrode is configured as the common electrode, and the light emitting module and the photovoltaic module are integrated as an integrated device, simplifying the machining process of the integrated device, and omitting a need of an additional production apparatus. Therefore, the manufacturing can be completed using the apparatuses used in conventional process, greatly reducing the production costs.

Although the present invention is described with reference to the specific embodiments in this specification, but it is to be understood that, these embodiments are merely examples of the principle and application of the present invention. Therefore, it is to be understood that various modifications can be made to the exemplary embodiments, and other arrangement can be designed without departing from the spirit and scope of the present invention defined by the claims. It is to be understood that different dependent claims and features described in the specification can be combined by using a method different from the method described in original claims. It is to be further understood that the features described with reference to a separate embodiment can be used in other embodiments.

What is claimed is:

1. An organic light emitting device, comprising:
a first electrode disposed on an array substrate;
a light emitting module disposed on the first electrode;
a second electrode disposed on a surface of the light emitting module away from the first electrode;
a photovoltaic module disposed on a surface of the second electrode away from the light emitting module; and
a third electrode disposed on a surface of the photovoltaic module away from the second electrode.

2. The organic light emitting device as claimed in claim 1, wherein the light emitting module comprises:
a light emitting layer disposed between the first electrode and the second electrode;
a first hole function layer disposed between the light emitting layer and the first electrode; and
a first electron function layer disposed between the light emitting layer and the second electrode.

3. The organic light emitting device as claimed in claim 2, wherein
the first hole function layer comprises:
a first hole transport layer disposed on a surface of the light emitting layer away from the first electron function layer; and
a first hole injection layer disposed on a surface of the first hole transport layer away from the light emitting layer; and
the first electron function layer comprises:
a first electron transport layer disposed on a surface of the light emitting layer away from the first hole function layer; and
a first electron injection layer disposed on a surface of the first electron transport layer away from the light emitting layer.

4. The organic light emitting device as claimed in claim 1, wherein the photovoltaic module comprises:
a light absorption layer disposed between the second electrode and the third electrode;
a second electron function layer disposed between the light absorption layer and the second electrode; and
a second hole function layer disposed between the light absorption layer and the third electrode.

5. The organic light emitting device as claimed in claim 1, wherein materials of the first electrode and the third electrode comprise transparent conductive oxide, and a material of the second electrode comprises metal.

6. The organic light emitting device as claimed in claim 1, wherein a thickness of the first electrode ranges from 10 to 50 nanometers, a thickness of the second electrode ranges from 100 to 200 nanometers, and a thickness of the third electrode ranges from 50 to 80 nanometers.

7. A method for manufacturing an organic light emitting device, comprising following steps:
manufacturing a first electrode on an array substrate;
manufacturing a light emitting module on the first electrode;
manufacturing a second electrode on the light emitting module;
manufacturing a photovoltaic module on the second electrode; and
manufacturing a third electrode on the photovoltaic module.

8. The method for manufacturing an organic light emitting device as claimed in claim 7, wherein the step of manufacturing the light emitting module on the first electrode comprises:
manufacturing a first hole function layer on the first electrode;
manufacturing a light emitting layer on the first hole function layer; and
manufacturing a first electron function layer on the light emitting layer.

9. The method for manufacturing an organic light emitting device as claimed in claim 7, wherein the step of manufacturing the photovoltaic module on the second electrode comprises:
manufacturing a second electron function layer on the second electrode;
manufacturing a light absorption layer on the second electron function layer; and
manufacturing a second hole function layer on the light absorption layer.

10. A display device, comprising the organic light emitting device as claimed in claim 1.
